(19) United States
(12) Patent Application Publication
(10) Pub. No.: US 2026/0026312 A1
(43) Pub. Date: Jan. 22, 2026

(54) ELECTRONIC DEVICE AND MANUFACTURING METHOD THEREOF

(71) Applicant: InnoLux Corporation, Miao-Li County (TW)

(72) Inventors: Wei-Yuan Cheng, Miao-Li County (TW); Ju-Li Wang, Miao-Li County (TW); Po-Yun Hsu, Miao-Li County (TW)

(73) Assignee: InnoLux Corporation, Miao-Li County (TW)

(21) Appl. No.: 19/245,444

(22) Filed: Jun. 23, 2025

Related U.S. Application Data
(60) Provisional application No. 63/673,791, filed on Jul. 22, 2024.

(30) Foreign Application Priority Data
Mar. 17, 2025 (CN) 202510308283.4

(51) Int. Cl. H01L 23/00; H01L 21/66; H01L 23/13; H01L 23/498

(52) U.S. Cl. CPC H01L 24/32; H01L 22/12; H01L 23/13; H01L 23/49827; H01L 24/24; H01L 24/73; H01L 24/83; H01L 2224/24227; H01L 2224/32225; H01L 2224/73267; H01L 2224/83191

(57) ABSTRACT

An electronic device and a manufacturing method thereof are provided. The electronic device includes a substrate, at least one electronic unit, an adhesive layer, an insulating layer, and a conductive structure. The substrate has at least one recess. The electronic unit is disposed in the recess, and the adhesive layer is disposed between the electronic unit and a bottom surface of the recess. The insulating layer is disposed on the electronic unit and the recess. The conductive structure is disposed on the insulating layer, and the conductive structure penetrates through the insulating layer to be electrically connected to the electronic unit.

### CROSS REFERENCE TO RELATED APPLICATION

This application claims the benefit of U.S. Provisional Application No. 63/673,791, filed on Jul. 22, 2024. The content of the application is incorporated herein by reference.

### BACKGROUND OF THE DISCLOSURE

### 1. Field of the Disclosure

The present disclosure relates to an electronic device and a manufacturing method thereof, and particularly to an electronic device and a manufacturing method thereof that disposes an electronic unit in a recess of a substrate.

### 2. Description of the Prior Art

Recently, semiconductor devices or package devices formed by 2.5D or 3D methods for packaging stacks are widely applied to electronic devices in various fields, such as communication, frequency modulation, vehicle or display, to increase the density of electronic units. In order to package stacks, a through via structure has been developed in a substrate to electrically connect an element on the upper surface of the substrate to another element on the lower surface of the substrate. However, the transmission path of the through via structure is still limited by the thickness of the substrate, which in turn affects the performance of the electronic device. Therefore, to shorten the transmission path between electronic units to improve the performance of the electronic device is one of objectives in this field.

### SUMMARY OF THE DISCLOSURE

It is an objective of the present disclosure to provide an electronic device and a manufacturing method thereof to solve the aforementioned problems.

According to an embodiment of the present disclosure, a manufacturing method of an electronic device is provided. The manufacturing method includes providing a carrier; providing a plurality of electronic units on the carrier; providing a substrate having a plurality of recesses; providing an adhesive layer on the plurality of electronic units or in the plurality of recesses, such that the plurality of electronic units are fixed on the substrate through the adhesive layer, and the plurality of electronic units are located in the plurality of recesses, respectively; removing the carrier; providing an insulating layer disposed on the plurality of electronic units and the plurality of recesses; and providing a conductive structure disposed on the insulating layer, wherein the conductive structure penetrates through the insulating layer to be electrically connected to at least one of the plurality of electronic units.

According to an embodiment of the present disclosure, an electronic device is provided and includes a substrate, at least one electronic unit, an adhesive layer, an insulating layer, and a conductive structure. The substrate has at least one recess. The electronic unit is disposed in the recess, and the adhesive layer is disposed between the electronic unit and a bottom surface of the recess. The insulating layer is disposed on the electronic unit and the recess. The conductive structure is disposed on the insulating layer, and the conductive structure penetrates through the insulating layer to be electrically connected to the electronic unit. A surface roughness of the recess is greater than a surface roughness of the electronic unit.

In the manufacturing method of the electronic device of the present disclosure, since the back surfaces of the electronic units are fixed in the recesses of the substrate by the adhesive layer, the levelness and position consistency of the electronic units fixed in the recesses may be improved in the case that flatness of the bottom surfaces of the recesses is not good. As a result, the impact on the resolution of the circuit structure formed subsequently may be lowered, or the yield of the subsequent process may be improved.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 to FIG. 3 schematically illustrate structures in different steps of a manufacturing method of an electronic device according to a first embodiment of the present disclosure in different steps.

FIG. 4 schematically illustrates the structures when the adhesive layers are disposed on the electronic units according to some examples of the present disclosure.

FIG. 5 schematically illustrates an electronic device in a region R according to the first embodiment of the present disclosure.

FIG. 6 schematically illustrates enlarged schematic diagrams of the electronic device in the region R according to some examples of the present disclosure.

FIG. 7 schematically illustrates cross-sectional views of structures in the step of providing the adhesive layer on the electronic units and the step of fixing the electronic units on the substrate according to some embodiments of the present disclosure.

FIG. 8 schematically illustrates cross-sectional views of structures in the step of providing the adhesive layer on the electronic units and the step of fixing the electronic units on the substrate according to some embodiments of the present disclosure.

FIG. 9 schematically illustrates cross-sectional views of structures in the step of providing the adhesive layer on the electronic units and the step of fixing the electronic units on the substrate according to some embodiments of the present disclosure.

FIG. 10 schematically illustrates a cross-sectional view of an electronic device according to a second embodiment of the present disclosure.

FIG. 11 schematically illustrates a cross-sectional view of an electronic device according to a third embodiment of the present disclosure.

### DETAILED DESCRIPTION

The contents of the present disclosure will be described in detail with reference to specific embodiments and drawings. It is noted that, for purposes of illustrative clarity and ease of understanding by the readers, the following drawings in the present disclosure may be a simplified illustrations, and elements therein may not be drawn to scale. The numbers and sizes of the elements in the drawings are merely illustrative and are not intended to limit the scope of the present disclosure.

Certain terms are used throughout the specification and the appended claims of the present disclosure to refer to specific elements. Those skilled in the art should understand that electronic equipment manufacturers may refer to an element by different names, and this document does not intend to distinguish between elements that differ in name but not in function. In the following specification and claims, the terms “comprise”, “include” and “have” are open-ended fashion, so they should be interpreted as “including but not limited to . . . ”.

The ordinal numbers used in the specification and the appended claims, such as “first”, “second”, etc., are used to describe the elements of the claims. This does not mean that the element has any previous ordinal numbers, nor does this represent the order of a certain element and another element, or the sequence in a manufacturing method. These ordinal numbers are merely used to make a claimed element with a certain name be clearly distinguishable from another claimed element with the same name.

In addition, when one element or layer is “connected to” another element or layer, it may be understood that the element or layer is directly connected to the another element or layer physically or electrically, and alternatively, the two may be physically or electrically connected through other element or layer (indirectly). On the contrary, when the element or layer is “directly connected to” another element or layer, it may be understood that there is no other element or layer between the two for physical or electrical connection. The term “connect” may include means of “directly connect” or “indirectly connect”. Besides, the term “electrically connect” or “couple” includes any direct or indirect means of electrical connection.

In the present disclosure, when one element is “disposed on” another element, the manufacturing procedure or sequence of forming the element and the another element is not limited thereto. In the present disclosure, when one element is “disposed on” another element, it may include one element is disposed on a side wall of another element.

As disclosed herein, the terms “approximately”, “essentially”, “about”, or “substantially” generally mean within 10%, 5%, 3%, 2%, 1%, or 0.5% of the reported numerical value or range. The numbers given herein are approximated numbers, and that is, without specifically describing the with terms “approximately”, “essentially”, “about”, or “substantially”, it may still imply the meaning of the terms “approximately”, “essentially”, “about”, or “substantially”.

The term “between a number A and a number B” is interpreted as including the number A and the number B or as including at least one of the number A and the number B, and as including other numbers between the number A and the number B.

In the present disclosure, the depth, thickness, length, width, height, distance, and aperture may be measured by using an optical microscope (OM), a scanning electron microscope (SEM) or other approaches, but not limited thereto.

In the present disclosure, the definition of roughness may be a peak-to-valley distance of 0.15 μm to 1 μm of surface undulations observed by a SEM. The measurement of determining the roughness may include using a SEM or a transmission electron microscope (TEM), etc. to observe peaks and valleys of surface undulations in a proper magnified ratio, and comparing the surface undulations by taking a unit length (e.g., 10 μm) to obtain its roughness range. Here, the term “proper magnified ratio” means at least one surface may be observed a roughness (Rz) or an averaged roughness (Ra) with at least 10 peaks in the visual field in this magnified ratio.

It should be understood that, according to the following embodiments, features of different embodiments may be replaced, recombined or mixed to constitute other embodiments without departing from the spirit of the present disclosure. The features of various embodiments may be mixed arbitrarily and used in different embodiments without departing from or conflicting with the spirit of the present disclosure.

Unless otherwise defined, all terms (including technical and scientific terms) used herein have the same meaning as commonly understood by those skilled in the art. It should be understood that these terms, such as those defined in commonly used dictionaries, should be interpreted as having meaning consistent with the relevant technology and the background or context of the present disclosure, and should not be interpreted in an idealized or excessively formal way, unless there is a specific definition in the embodiments of the present disclosure.

An electronic device of the present disclosure may, for example, include a display device, a light emitting device, a sensing device, an antenna device, a touch device, a tiled device, a package device, or other suitable electronic devices, but not limited thereto.

The electronic device may, for example, be a bendable, stretchable, foldable, rollable, and/or flexible electronic device, but not limited thereto. The display device may, for example, be applied to a laptop, a public display, a tiled display, a car display, a touch display, a TV, a monitor, a smartphone, a tablet, a light source module, a lighting equipment, a military equipment, or an electronic device applied to the aforementioned products, but not limited thereto. The sensing device may, for example, be a sensing device used for detecting variation in capacitances, light, heat, or ultrasound, but not limited thereto. The sensing device may, for example, include a bio-sensor, a touch sensor, a fingerprint sensor, other suitable sensors, or any combination of the aforementioned sensors. The display device may, for example, include liquid crystal molecules, a light emitting diode, a fluorescent material, a phosphor material, other suitable display media, or a combination of the aforementioned display media, but not limited thereto. The light emitting diode may, for example, include an organic light emitting diode (OLED), a mini light emitting diode (mini LED), a micro light emitting diode (micro LED), or a quantum dot light emitting diode (e.g., QLED or QDLED), but not limited thereto. The antenna device may include liquid crystal antenna, varactor diode antenna, or antennas of other types, but not limited thereto. The tiled device may, for example, include a tiled display device or a tiled antenna device, but not limited thereto. Furthermore, the appearance of the electronic device may be, for example, rectangular, circular, polygonal, a shape with curved edges, curved or other suitable shapes. The electronic device may have peripheral systems, such as a driving system, a control system, a light source system, a shelf system, etc. The electronic device may include electronic units, in which the electronic units may include a passive element and an active element, and for example, include a capacitor, a resistor, an inductor, a diode, a transistor, a sensor, etc. It is noted that the electronic device of the present disclosure may be any combination of the above-mentioned devices, but not limited thereto. The manufacturing method of the package device of the present disclosure may, for example, be applied to a wafer-level package (WLP) process or a panel-level package (PLP) process, wherein the WLP or the PLP may include a chip-first process or a chip-last process, but not limited thereto. The electronic device of the present disclosure may, for example, be applied to a package device, a power module, a display device, a light emitting device, a backlight device, an antenna device, a sensing device, or a tiled device, but not limited thereto. The electronic device may include high bandwidth memory (HBM) package, system on a chip (SoC), system in a package (SiP), antenna in package (AiP), co-packaged optics (CPO), or any combination of the aforementioned devices, but not limited thereto.

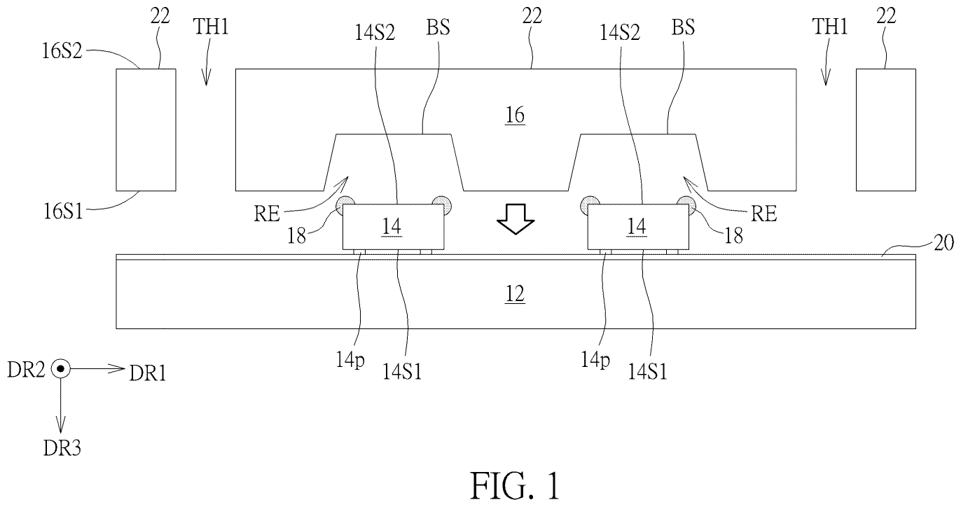

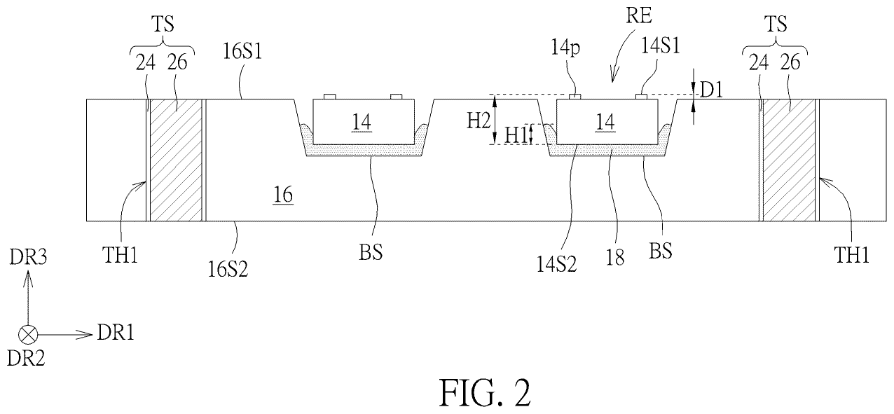

The following figures show a direction DR1, a direction DR2, and a direction DR3. The direction DR3 may be a normal direction or a top view direction of the electronic device, and as shown in FIG. 1, the direction DR3 may be perpendicular to a first surface 16S1 of a substrate 16. The direction DR1 and the direction DR2 each may be a horizontal direction and may be perpendicular to the direction DR3. As shown in FIG. 2, the direction DR1 and the direction DR2 may be parallel to the first surface 16S1 of the substrate 16, and the direction DR1 and the direction DR2 may be perpendicular to each other. The following figures may describe the spatial relations of structures based on the direction DR1, the direction DR2, and the direction DR3.

Refer to FIG. 1 to FIG. 3, which schematically illustrate structures in different steps of a manufacturing method of an electronic device according to a first embodiment of the present disclosure in different steps. As shown in FIG. 1 to FIG. 3, the manufacturing method of the electronic device 1 may at least include the following steps: providing a carrier 12; providing a plurality of electronic units 14 disposed on the carrier 12; providing a substrate 16 having a plurality of recesses RE; providing an adhesive layer 18 on the electronic units 14 or in the recesses RE, such that the electronic units 14 are fixed on the substrate 16 through the adhesive layer 18, and the electronic units 14 are respectively located in the recesses RE; removing the carrier 12; providing an insulating layer IN1 disposed on the electronic units 14 and the recesses RE; and providing a conductive structure CS1 disposed on the insulating layer IN1, wherein the conductive structure CS1 penetrates through the insulating layer IN1 to be electrically connected to at least one of the electronic units 14. It is noted that through the above manufacturing method, levelness and position consistency of the electronic units 14 while being bonded in the recesses RE may be improved in the case that the bottom surfaces and/or sidewalls of the recesses RE do not have good flatness. The manufacturing method of the present disclosure is not limited to the above steps, and other steps may be performed before, after or during any of the above steps.

The manufacturing method of the electronic device 1 in this embodiment is further described in detail in the following contents with reference to FIG. 1 to FIG. 3. As shown in FIG. 1, the step of providing the carrier 12 may include disposing a release layer 20 on the carrier 12 to temporarily fix the electronic units 14 in the subsequent processes and to help separate the electronic units 14 from the carrier 12. The releasing method of the release layer 20 may include photo-releasing, thermal-releasing, other suitable methods or a combination thereof. Based on the releasing method, the release layer 20 may be paired with different types of carriers 12. For example, the photo-releasing type of the release layer 20 may be used with a transparent glass substrate. The thermal-releasing type of the release layer 20 may be used with a steel plate. The release layer 20 may, for example, include an ultraviolet (UV) release film, a heat release tape (HRT), other suitable materials or a combination thereof. In some embodiments, before forming the release layer 20, an anti-warping layer (not shown) may be optionally formed on the carrier 12 to reduce warpage generated in the subsequent processes and improve process yield. The anti-warping layer may include silicon oxide, silicon nitride, silicon oxynitride, tetrathoxysilane (TEOS) or other suitable materials. The carrier 12 may be used to carry the electronic units 14. The carrier 12 may include the steel plate, the transparent glass substrate, a silicon substrate or other suitable substrates.

The electronic unit 14 may include a chip, a chip package structure, a chip assembly structure or other types of element structures. The electronic unit 14 may have a surface 14S1 and a surface 1452 opposite to each other, wherein a surface of the electronic unit 14 with bonding pads 14p may be, for example, the surface 14S1, that is, the surface of one of the bonding pads 14p may be a part of the surface 14S1, and a surface of the electronic unit 14 opposite to the surface 14S1 is the surface 14S2. For example, the surface 14S1 may be an active surface of the electronic unit 14, and the surface 1452 may be a back surface of the electronic unit 14. It should be understood that the bonding pads 14p may be input/output pads (I/O pads) of the electronic unit 14, and the bonding pads 14p may include, for example, aluminum, nickel, gold, copper, nitride or other suitable conductive materials.

After the step of providing the carrier 12, the electronic units 14 may be disposed on the release layer 20 (or the carrier 12). It should be noted that the step of providing the electronic units 14 on the release layer 20 may be performed in a way that the surface 14S1 of the electronic unit 14 faces the release layer 20, such that the surface 14S2 of the electronic unit 14 may face upward. The step of providing the electronic units 14 may, for example, include a die bonding process or other suitable processes. In some embodiments, one of the electronic units 14 may be directly formed on the release layer 20, and in this case, the electronic unit 14 may, for example, include a capacitor, a resistor, an inductor, or other suitable components.

As shown in FIG. 1, the step of providing the substrate 16 does not affect the step of providing the carrier 12 and the step of providing the electronic units 14 on the release layer 20, and thus, the step of providing the substrate 16 may be performed before, after or during the step of providing the carrier 12 and/or the step of providing the electronic units 14 on the release layer 20.

The step of providing the substrate 16 may include forming the recesses RE on a surface of the substrate 16. The substrate 16 may, for example, have a first surface 16S1 and a second surface 16S2 opposite to each other, and in FIG. 1, the recesses RE may be formed on the first surface 16S1, but not limited thereto. In some embodiments, the recesses RE may alternatively be formed on the second surface 16S2. In the embodiment of FIG. 1, at least one through hole TH1 may be further formed in the substrate 16, wherein the through hole TH1 penetrates through the substrate 16, but not limited thereto.

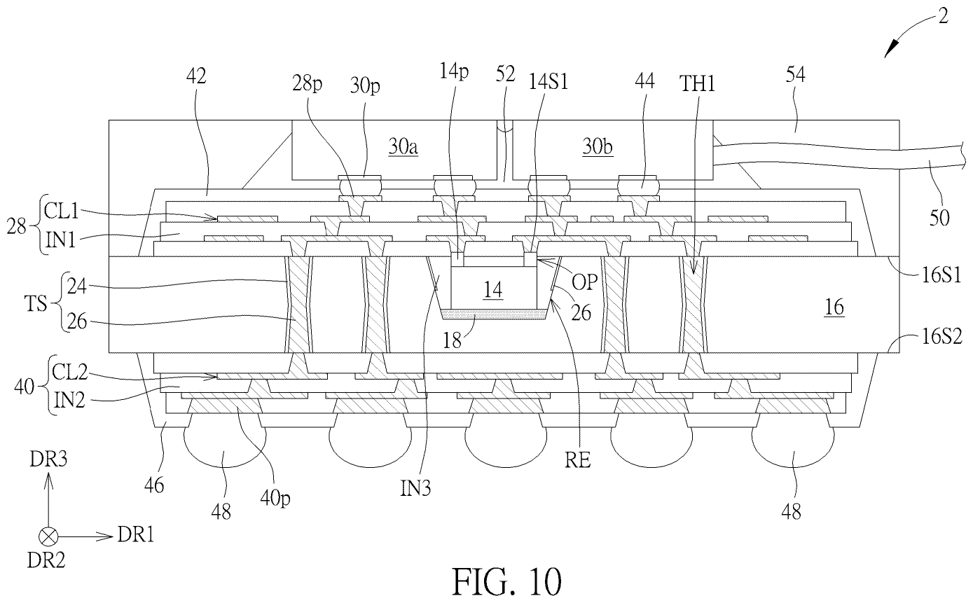

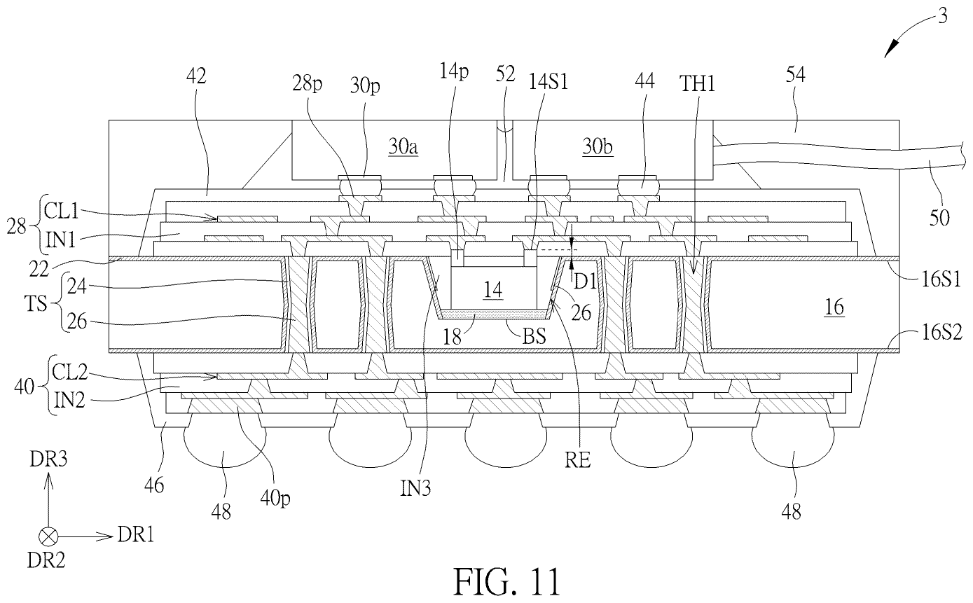

The method of forming the recesses RE and the through hole TH1 may include, for example, a modification process and an etching process or other suitable processes. The modification process may include, for example, a laser irradiation process or other suitable processes. Depending on the material of the substrate 16, the laser wavelength used in the laser irradiation process may vary, and the absorbance of the substrate 16 in the laser wavelength may be greater than or equal to 708. The etching process may include, for example, a wet etching process using an etchant or other suitable processes. According to some embodiments, the etchant may include an acidic or alkaline liquid, wherein the acidic etchant includes hydrofluoric acid, and the alkaline etchant includes sodium hydroxide, but not limited thereto. The etching process referred to in the present disclosure may be, for example, performed on the first surface 16S1 or the second surface 16S2 of the substrate 16 to form the through hole TH1, or performed simultaneously on the first surface 16S1 and the second surface 16S2 of the substrate 16, but not limited thereto. In some embodiments, in a cross-sectional view, the through hole TH1 may be rectangular, trapezoidal, inverted trapezoidal, dumbbell-shaped, hourglass-shaped (e.g., as shown in FIG. 10 or FIG. 11) or other suitable shapes.

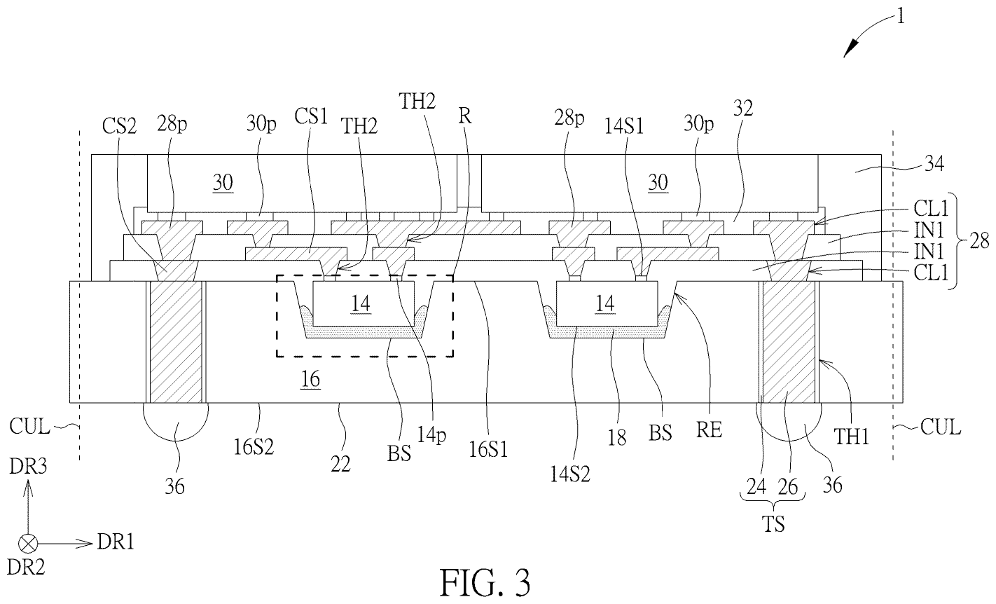

The transmittance of the substrate 16 may be, for example, greater than 80%. As an example, the substrate 16 may include a glass substrate, a transparent material containing silicon, an optical layer, an acrylic plate, other transparent materials, or a combination thereof, and the substrate 16 has certain rigidity and insulation. In other words, the rigidity of the substrate 16 may be greater than that of a circuit structure (e.g., a circuit structure 28 of FIG. 3) formed in subsequent steps, and for example, the rigidity of the substrate 16 is greater than that of an insulating layer of the circuit structure (e.g., an insulating layer IN1 of FIG. 3), so that as the substrate 16 is used for carrying the circuit structure, the warpage may be mitigated, but not limited thereto. Alternatively, the dielectric loss (or dissipation factor) of the substrate 16 is less than that of the insulating layer of the circuit structure, so that the electrical performance of the electronic device 1 may be improved as the substrate 16 is used to carry the circuit structure, but not limited thereto.

After the step of providing the substrate 16, a buffer layer (e.g., the buffer layer 22 shown in FIG. 11) may be selectively formed on an exposed surface of the substrate 16. The buffer layer may at least cover corners of the substrate 16 to reduce cracks at the corners of the substrate 16, for example, cover the corner formed by the sidewall of the through hole TH1 (or the sidewall of one of the recesses RE) connected to the first surface 16S1 or the second surface 16S2, and the buffer layer may expose the bottom surfaces BS of the recesses RE. The method of forming the buffer layer may include a deposition process or other suitable processes. The deposition process may, for example, include coating, evaporation, atomic layer deposition or other physical deposition processes or chemical deposition processes. In some embodiments, after the step of providing the substrate 16, the buffer layer may not be formed.

The material of the buffer layer may include, for example, an organic material or an inorganic material, wherein the organic material may include, for example, polyimide (PI), poly-p-xylylene (Parylene), benzocyclobutene (BCB), epoxy, polycarbonate (PC), polyethylene terephthalate (PET), polyethylene naphthalate (PEN), polymer or other suitable materials. The buffer layer may be, for example, a single layer or multilayer structure. When the buffer layer is the multilayer structure, the buffer layer may include a structure of an inorganic material layer, an organic material layer, and an inorganic material layer stacked in sequence, a structure of an organic material layer, an inorganic material layer, and an organic material layer stacked in sequence, or other suitable structures. The inorganic material may include an oxide, a nitride, a suitable ceramic material or a combination thereof, but not limited thereto. The toughness of the buffer layer may be greater than or equal to 0.1 kilojoules per square meter (kJ/m²) and less than or equal to 100 KJ/m² (i.e., 0.1 KJ/m²≤toughness of the buffer layer≤100 KJ/m²). In the present disclosure, the toughness of a layer may be obtained by integrating an area under a stress-strain curve, and the stress-strain curve may be obtained by performing a tensile test on the layer using a universal testing machine (UTM). A dielectric loss (Df) of the buffer layer may be less than that of the substrate 16. For example, the dielectric loss of the buffer layer may be less than 0.1 while the operating frequency of the buffer layer is greater than or equal to 10 MHz, thereby reducing the impact on signal transmission and particularly reducing the impact on the transmission of high-frequency signals.

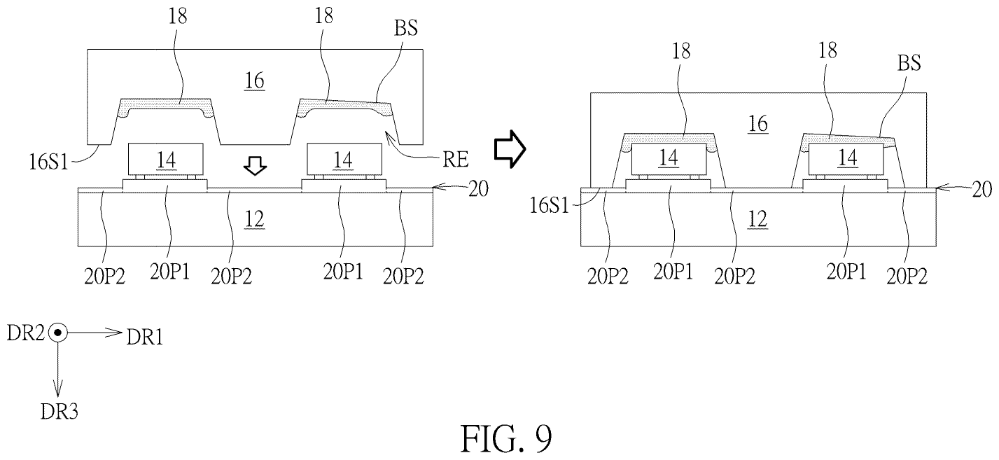

In the embodiment of FIG. 1, after the step of providing the substrate 16 (or the step of forming the buffer layer) and the step of providing the electronic units 14 on the release layer 20, at least a portion of the adhesive layer 18 is disposed on the surface 14S2 of each electronic unit 14, but not limited thereto. In some embodiments, when the electronic units 14 are not yet fixed on the substrate 16, the adhesive layer 18 may be disposed in the recesses RE, such as shown in FIG. 9. The adhesive layer 18 may, for example, include BCB, poly (p-phenylene benzobisoxazole) (PBO), optical clear adhesive (OCA), polycarbonate adhesive, transparent epoxy resin or other suitable adhesive materials. The adhesive layer 18 may have a water vapor transmission rate (WVTR) less than or equal to 5×10⁻² g/m²·day. The adhesive layer 18 may have a transmittance greater than or equal to 80%. According to some embodiments, the adhesive layer 18 may contain some bubbles, wherein the proportion of the bubbles in the adhesive layer 18 is less than or equal to 5 vol %. If the proportion of the bubbles in the adhesive layer 18 is greater than 5 vol % after testing, another processing step, such as heating, pressurizing, other suitable steps, or a combination thereof, may be provided, but not limited thereto.

It should be noted that, between the step of providing the substrate 16 and the step of disposing the adhesive layer 18 on the electronic units 14, the manufacturing method of the electronic device 1 may further include inspecting the recesses RE and providing an amount of the adhesive layer 18 according to states of the recesses RE. The term “amount” of this disclosure may refer to volume, weight, size or other suitable units. In other words, the step of inspecting the recesses RE may include inspecting the structural states of the recesses RE, for example inspecting the roughness or flatness of the bottom surfaces BS and the sidewalls of the recesses RE, the levelness of the bottom surfaces of the recesses RE, the difference between different recesses RE, or other structural features. Since the structural states of different recesses RE may be different, through inspecting the structural states of the recesses RE, the amounts of the adhesive layer 18 on the surfaces 1452 of the corresponding electronic units 14 may vary according to the structural states of different recesses RE, so as to improve the position consistency of different electronic units 14 relative to the first surface 16S1 of the substrate 16 as the electronic units 14 are bonded to the substrate 16. Accordingly, the impact on the resolution of the circuit structure formed in subsequent steps may be reduced, or the yields of the subsequent processes may be improved.

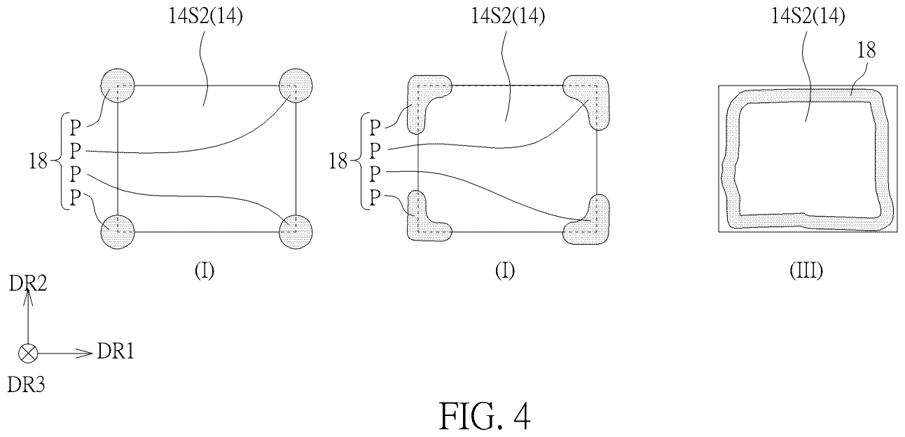

Refer to FIG. 4, which schematically illustrates the structures when the adhesive layers are disposed on the electronic units according to some examples of the present disclosure. As shown in FIG. 4, the step of providing the adhesive layer 18 on the electronic units 14 includes coating the adhesive layer 18 on a portion of the surface 14S2 of one of the electronic units 14 and exposing another portion of the surface 14S2 of the electronic unit 14. In an example (I) of FIG. 4, the portion of the surface 1452 of the electronic unit 14 coated by the adhesive layer 18 may be four corners of the surface 1452, and in other words, the adhesive layer 18 may include four portions P respectively disposed on the corners of the surface 14S2. In another example (II) of FIG. 4, the portion of the surface 14S2 of the electronic unit 14 coated by the adhesive layer 18 may be the four corners of the surface 1452 and portions of side edges of the surface 1452 connected to the corners. In other words, the adhesive layer 18 may include four portions P, and each portion P is disposed on the corresponding corner of the surface 14S2 and two side edges connected to the corresponding corner. In another example (III) of FIG. 4, the adhesive layer 18 coated on the surface 14S2 of the electronic unit 14 may be, for example, annular. In a top view, a ratio of an overlapping area of the adhesive layer 18 and the surface 1452 of the corresponding electronic unit 14 to the area of the surface 1452 of the electronic unit 14 may be greater than or equal to 0.1 and less than or equal to 1 (i.e., 0.1≤the overlapping area/the area of the surface 1452≤1), so as to avoid disposing excessive amount of the adhesive layer 18. Therefore, as the electronic unit 14 is fixed on the substrate 16, the probability of the adhesive layer 18 extending onto the surface 14S1 of the electronic unit 14 may be reduced.

As shown in FIG. 1, after the adhesive layer 18 is provided, the substrate 16 may be turned upside down, such that the first surface 16S1 of the substrate 16 having the recesses RE faces downward. Then, the recesses RE of the substrate 16 may be disposed corresponding to the electronic units 14, respectively, such that the electronic units 14 may be fixed on the substrate 16 through the adhesive layer 18, as shown in FIG. 2. In this embodiment, the electronic units 14 may be respectively accommodated in the recesses RE.

It should be noted that, as shown in FIG. 2, the adhesive layer 18 has a leveling property, and the thickness of the adhesive layer 18 may be greater than the peak-to-valley distance of the surface undulations on the bottom surface BS in the direction DR3. In other words, the thickness of the adhesive layer 18 is greater than the roughness of the bottom surface BS, so that the surface of the adhesive layer 18 facing the electronic units 14 may not be affected by the roughness of the bottom surfaces BS and may be flat. Through the provision of the adhesive layer 18, the distance between the surface 14S1 of one of the electronic units 14 and the first surface 16S1 of the substrate 16 may be controlled within a predetermined range. Furthermore, difference in distances between the surfaces 14S1 of different electronic units 14 and the first surface 16S1 of the substrate 16 may be reduced, thereby enhancing the position consistency of the electronic units 14. As a result, the resolution of the circuit structure formed subsequently and/or the yields of the subsequent processes may be improved. For example, when the buffer layer is not formed on the substrate 16, the distance D1 between a horizontal plane of the surface 14S1 of each electronic unit 14 and a horizontal plane of the first surface 16S1 of the substrate 16 adjacent to the surface 14S1 may be less than or equal to 10 micrometers (μm). In other words, the horizontal plane of the surface 14S1 of one of the electronic units 14 may be lower, higher than, or coplanar with the horizontal plane of the first surface 16S1 of the substrate 16, and the distance D1 between the horizontal plane of the surface 14S1 and the horizontal plane of the first surface 16S1 may be less than or equal to 10 um to facilitate the formation of the subsequent circuit structure. In the present disclosure, the horizontal planes may be, for example, planes parallel to the direction DR1 and the direction DR2. In some embodiments, when the buffer layer (e.g., the buffer layer 22 shown in FIG. 11) is formed on the substrate 16, the distance D1 is the distance between the horizontal plane of the surface 14S1 of each electronic unit 14 and the horizontal plane of the outer surface of the buffer layer 22 located on the first surface 16S1. In some embodiments, the difference in the distances D1 corresponding to different electronic units 14 may be less than or equal to 5 μm.

As shown in FIG. 2, after the step of fixing the electronic units 14 on the substrate 16, the carrier 12 may be removed, for example, the release layer 20 and the carrier 12 may be removed simultaneously. After the carrier 12 is removed, the substrate 16 may be optionally turned upside down. Next, a mask (not shown) may be used to shield the recesses RE and the electronic units 14, and a seed layer 24 and a conductive layer 26 are sequentially formed on the sidewall of the through hole TH1 and a portion of the first surface 16S1 and a portion of the second surface 16S2 of the substrate 16 that are not shielded by the mask. The mask may, for example, include a dry film photoresist material or other suitable materials. Afterwards, a portion of the seed layer 24 and a portion of the conductive layer 26 located outside the through hole TH1 are removed to form a through via structure TS in the through hole TH1.

It should be noted that, in the embodiment of FIG. 2, when there is no buffer layer formed on the substrate 16, the through via structure TS may not protrude from the first surface 16S1 and the second surface 16S2 of the substrate 16. In other words, a projection of the through via structure TS along the direction DR3 on one of the horizontal planes may not overlap projections of the first surface 16S1 and the second surface 162 along the direction DR3 on the horizontal plane. Since the seed layer 24 and the conductive layer 26 including metal are not disposed on both the sidewall of the through hole TH1 and the first surface 16S1 or on both the sidewall of the through hole TH1 and the second surface 162 at the same time, risk of cracking of the substrate 16 at corners may be reduced or avoided. In some embodiments, when the buffer layer is formed on the substrate 16, the through via structure TS may not protrude from outer surfaces of the buffer layer respectively located on the first surface 16S1 and the second surface 16S2. In other words, the projection of the through via structure TS along the direction DR3 on one of the horizontal planes may not overlap the projections of the outer surfaces of the buffer layer located on the first surface 16S1 and the second surface 1682 along the direction DR3 on the horizontal plane.

As shown in FIG. 3, after the step of forming the through via structure TS, an insulating layer IN1 may be provided on the electronic units 14 and extended into the recesses RE. In this embodiment, the insulating layer IN1 may further be disposed on the first surface 16S1 of the substrate 16, but not limited thereto. The method of forming the insulating layer IN1 may include, for example, a deposition process or other suitable processes. After that, at least one through hole TH2 is formed in the insulating layer IN1, for example, by a photolithographic process combined with an etching process or other suitable processes. In the embodiment of FIG. 3, a plurality of through holes TH2 may be formed, wherein a part of the through holes TH2 may respectively expose pads 14p of the electronic units 14, and other part of the through holes TH2 may expose the via structure TS.

Subsequently, the conductive structure CS1 is provided, in which the conductive structure CS1 is disposed on the insulating layer IN1 and penetrates through the insulating layer IN1 to be electrically connected to at least one of the electronic units 14. Specifically, a conductive layer CL1 including the conductive structure CS1 may be formed on the insulating layer IN1, and the conductive structure CS1 may be disposed in one of the through holes TH2 corresponding to one of the pads 14p, such that the conductive structure CS1 may be electrically connected to one of the electronic units 14, but not limited thereto. In some embodiments, the conductive layer CL1 may include another conductive structure CS1 disposed in the through holes TH2 corresponding to the pads 14p of different electronic units 14 at the same time to electrically connect different electronic units 14 to each other. After the conductive layer CL1 is formed, the step of providing the insulating layer IN1 and the step of forming the conductive layer CL1 may be optionally repeated at least once to form the circuit structure 28.

The circuit structure 28 may include at least one conductive layer CL1 and at least one insulating layer IN1 to redistribute wirings and/or further increase fan-out areas of the wirings, or different electronic units may be electrically connected to each other through the circuit structure 28. Alternatively, the circuit structure 28 may be a substrate used as an electrical interface routing between one circuit and another circuit. A purpose of the circuit structure 28 is to expand wirings to have greater distance between the wirings or to redistribute the wirings to other wirings with different distance. In other words, the circuit structure 28 in the present disclosure (e.g., the circuit structure 28 or the circuit structure 40 of FIG. 10 or FIG. 11) may be a redistribution layer/structure. The circuit structure mentioned here or in the following contents may be electrically connected to each chip or each electronic unit through connecting elements or other bonding elements. In some embodiments, the numbers and the circuit layout of the conductive layer CL1 and the insulating layer IN1 of the circuit structure 28 may be adjusted according to requirements.

In FIG. 3, the conductive layer CL1 may further include a conductive structure CS2 disposed in one of the through holes TH2 exposing the through via structure TS. A width of a lower surface of the conductive structure CS2 facing the through via structure TS may be less than a width of an upper surface of the through via structure TS facing the conductive structure CS2, so that the conductive structure CS2 and the through via structure TS that include metal are not disposed at the corner formed by the sidewall of the through hole TH1 and the first surface 16S1. Therefore, the risk of cracking of the corner of the substrate 16 may be reduced or avoided.

In the embodiment of FIG. 3, at least a portion of the insulating layer IN1 of the circuit structure 28 may extend into one of the recesses RE and be located between the sidewall of one of the electronic units 14 and the sidewall of the recess RE; that is, an insulating layer disposed in the recess RE may be formed of the insulating layer IN1 of the circuit structure 28, but not limited thereto. In some embodiments, the manufacturing method of the electronic device 1 may include disposing another insulating layer (e.g., the insulating layer IN3 shown in FIG. 10 or FIG. 11) in the recesses RE, and then forming the circuit structure 28, such that the insulating layer disposed in the recesses RE may be different from the insulating layer IN1 of the circuit structure 28, but not limited thereto.

The step of forming the circuit structure 28 may, for example, include alternately forming the insulating layer IN1 and the conductive layer CL1. The method of forming the insulating layer IN1 and the conductive layer CL1 may include a deposition process, an oxidation process, an annealing process, a surface treatment or other processes. The “surface treatment” referred to in the present disclosure means that in the case that each layer is formed in sequence along the top view direction (direction DR3) of the electronic device, as an element B is stacked, formed or disposed on an element A, a surface roughening step is performed on the element A to enhance the bonding strength between the element A and the element B, wherein the element A and the element B may include the same material or not. For example, before forming the circuit structure 28 on the substrate 16, the surface roughening step may be performed on the surface of the substrate 16. Alternatively, during the processes of forming the conductive layer CL1 and the insulating layer IN1 alternately stacked, the surface roughening step may be performed on the surface of the conductive layer CL1 and/or the surface of the insulating layer IN1. The surface roughening step may include laser, wet etching, dry etching, plasma treatment, transfer printing or a combination thereof, but not limited thereto.

For example, the insulating layer IN1 may include polyimide (PI), photosensitive polyimide (PSPI), Ajinomoto build-up film (ABF), silicon oxide (SiOx), silicon nitride (SiNx), silicon oxynitride (SiOxNy) or other suitable dielectric materials. The conductive layer CL1 may include a conductive material, such as copper (Cu), titanium (Ti), aluminum (Al), molybdenum (Mo), nickel (Ni), ruthenium (Ru), tantalum (Ta), tungsten (W), nitride, carbide or other conductive materials or any combination thereof, but not limited thereto.

The circuit structure 28 of FIG. 3 takes two conductive layers CL1 and two insulating layers IN1 as an example, but not limited thereto. In FIG. 3, the conductive layer CL1 farthest from the substrate 16 may include a plurality of pads 28p, and the insulating layer IN1 may include a plurality of through holes TH2, in which the pads 28p may be electrically connected to the corresponding electronic units 14 and the corresponding through via structure TS through the through holes TH2, but not limited thereto.

After the step of forming the circuit structure 28, at least one electronic unit 30 may be provided on the circuit structure 28. In the embodiment of FIG. 3, the number of electronic units 30 is multiple, but not limited thereto. For example, the electronic units 30 may be bonded to the pads 28p through corresponding connecting elements (not shown), so that the pads 30p of the electronic unit 30 are electrically connected to the pads 28p of the circuit structure 28 through the connecting elements respectively, but not limited thereto. The connecting elements may include, for example, solder balls, nickel, gold, copper, gallium or other suitable conductive materials. In some embodiments, the electronic units 30 and the circuit structure 28 may be bonded to each other by a metal-to-metal direct bonding process, a hybrid bonding process or other suitable processes. The metal-to-metal direct bonding process may include, for example, a copper-to-copper direct bonding process. The hybrid bonding process may include, for example, forming a dielectric layer on the electronic units 30 and another dielectric layer on the circuit structure 28, and then bonding these two dielectric layers, such that the electronic unit 30 is boned to the circuit structure 28.

In the embodiment of FIG. 3, after the electronic units 30 are provided, an adhesive layer 32 may be optionally provided between the circuit structure 28 and the electronic units 30 to enhance adhesion between the circuit structure 28 and the electronic units 30. The adhesive layer 32 may, for example, include an underfill material or other suitable materials. After the step of providing the electronic units 30 or the step of providing the adhesive layer 32, a protective layer 34 may be formed on the circuit structure 28 and the electronic units 30. The method of forming the protective layer 34 may, for example, include a molding process or other suitable processes. The protective layer 34 may include an encapsulation material or other suitable materials. The encapsulation material may, for example, include an epoxy molding compound (EMC) or other suitable organic materials.

In the embodiment of FIG. 3, the protective layer 34 may contact the substrate 16 (or the buffer layer), and for example, the protective layer 34 may extend to be on the substrate 16 to protect a side surface of the circuit structure 28, but not limited thereto. In some embodiments, the protective layer 34 may not be disposed on the side surface of the circuit structure 28.

In FIG. 3, part of the protective layer 34 on the back surfaces of the electronic units 30 may be selectively further removed to facilitate heat dissipation of the electronic units 30. In this case, the protective layer 34 may surround the electronic units 30, but not limited thereto. The step of removing part of the protective layer 34 on the electronic units 30 may include a grinding process or other suitable processes. In the present disclosure, an element “surrounds” another element may refer to that in a cross-sectional view of the electronic device, the element at least contacts a side surface of the other element.

As shown in FIG. 3, after the protective layer 34 is formed, a conductive member 36 may be formed on a lower surface of the through via structure TS. The conductive member 36 may include, for example, a solder ball or other suitable materials. Then, a singulation process may be performed, for example, along a cutting line CUL to form a single electronic device 1. The singulation process may include, for example, laser cutting, wheel cutting or other suitable cutting processes. The singulation process may be performed from the first surface 16S1 or the second surface 16S2 of the substrate 16, or performed from both the first surface 16S1 and the second surface 16S2. According to some embodiments, the laser wavelength used for cutting may be different from that used in the modification process, and for example, the laser wavelength used for cutting is greater than that used in the modification process.

The structure of the electronic device 1 of this embodiment is further detailed below. As shown in FIG. 3, the electronic device 1 of this embodiment may at least include the substrate 16, at least one of the electronic units 14, the adhesive layer 18, the insulating layer IN1, and the conductive structure CS1, wherein the substrate 16 has at least one of the recesses RE, and the electronic unit 14 is disposed in the recess RE. The adhesive layer 18 is disposed between the electronic unit 14 and the bottom surface BS of the recess RE to fix the electronic unit 14 in the recess RE. The insulating layer IN1 is disposed on the electronic unit 14 and the recess RE, and the conductive structure CS1 is disposed on the insulating layer IN1 and penetrates through the insulating layer IN1 to be electrically connected to the electronic unit 14. In addition, the surface roughness of the recess RE is greater than the surface roughness of the electronic unit 14.

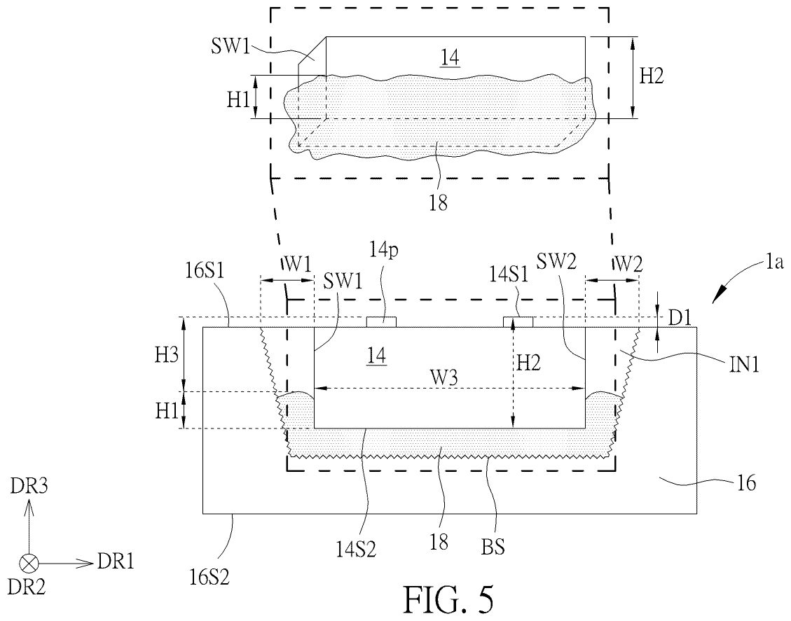

Refer to FIG. 5 for details. FIG. 5 schematically illustrates an electronic device in a region R according to the first embodiment of the present disclosure, wherein an upper portion of FIG. 5 schematically illustrates a side view of the electronic unit and the adhesive layer of a lower portion of FIG. 5. As shown in FIG. 3 and the lower portion of FIG. 5, the bottom surface BS and the sidewalls of the recess RE are rough surfaces, and the roughness of the bottom surface BS and the roughness of the sidewall are greater than the surface roughness of the electronic unit 14. For example, they are greater than the roughness of the surface 1452 of the electronic unit 14. The thickness of the adhesive layer 18 may be greater than a difference between highest point and lowest point (e.g., peak and valley) of the bottom surface BS of the recess RE, so that the impact of the rough surface of the recess RE on the position of the electronic unit 14 may be reduced.

In the lower portion of FIG. 5, the adhesive layer 18 may be squeezed by the electronic unit 14 and extend to be between the sidewall of the electronic unit 14 and the sidewall of the recess RE. For example, the ratio of a height H1 from a highest point of the adhesive layer 18 in the direction DR3 to the horizontal plane of the surface 14S2 of the electronic unit 14 to a thickness H2 of the electronic unit 14 may be greater than or equal to 0.2 and less than or equal to 0.8 (i.e., 0.2≤height H1/thickness H2≤0.8) to prevent excessive amount of the adhesive layer 18 to reduce the risk that the adhesive layer 18 extends onto the surface 14S1 of the electronic unit 14 while the electronic unit 14 is fixed on the substrate 16, or to prevent insufficient amount of the adhesive layer 18 to reduce the risk that the electronic unit 14 peels off the substrate 16. The thickness H2 of the electronic unit 14 may be, for example, a distance from the surface 14S1 to the surface 14S2 of the electronic unit 14. For example, a ratio of a height H3 from the highest point of the adhesive layer 18 to the horizontal plane of the surface 14S1 of the electronic unit 14 in the direction DR3 to the thickness H2 of the electronic unit 14 may be greater than or equal to 0.05 and less than or equal to 1 (i.e., 0.05≤height H3/thickness H2≤1), wherein the height H3 may be, for example, greater than or equal to 5 μm and less than or equal to 20 μm (i.e., 5 μm≤height H3≤20 μm).

In addition, a width W1 between a sidewall SW1 of the electronic unit 14 and an edge of the recess RE adjacent to the first surface 16S1 and a width W2 between another sidewall SW2 of the electronic unit 14 opposite to the sidewall SW1 and another edge of the recess RE adjacent to the first surface 16S1 and opposite to the edge may be less than or equal to 100 um, such that the electronic unit 14 is not close to the rough sidewall of the recess RE while being disposed. Accordingly, the impact of the sidewall of the recess RE on the position of the electronic unit 14 may be prevented. In the upper portion of FIG. 5, the adhesive layer 18 may extend from the surface 14S2 of the electronic unit 14 to the sidewall SW1 and the another sidewall, but not limited thereto. In some embodiments, the adhesive layer 18 may extend to all sidewalls of the electronic unit 14.

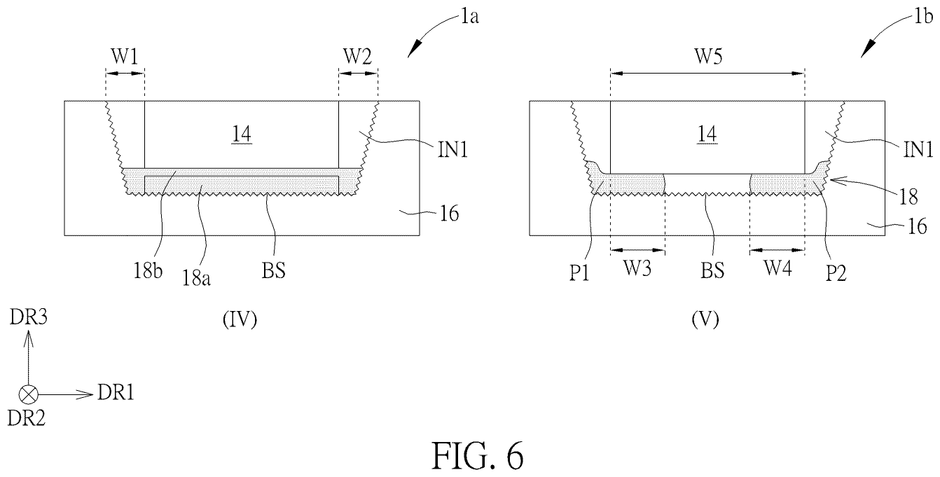

Refer to FIG. 6, which schematically illustrates enlarged schematic diagrams of the electronic device in the region R according to some examples of the present disclosure. As shown in example (IV) of FIG. 6, the electronic device la may include a plurality of adhesive layers, for example, an adhesive layer 18a and an adhesive layer 18b. The adhesive layer 18a is disposed between the electronic unit 14 and the bottom surface BS of the recess RE, and the adhesive layer 18b is disposed between the electronic unit 14 and the adhesive layer 18a. The support provided by the adhesive layer 18a may be better than that provided by the adhesive layer 18b, and the leveling property of the adhesive layer 18b may be greater than the leveling property of the adhesive layer 18a, that is to say, a flatness of the of the adhesive layer 18b is greater than a flatness of the of the adhesive layer 18a. The adhesive layer 18a and the adhesive layer 18b may, for example, include optical clear adhesive (OCA), polycarbonate adhesive, transparent epoxy resin or other suitable adhesive materials. In the disclosure, a flatness or a levelness of a surface of an element would be measured by following ISO 12781, but not limited thereto.

As shown in example (V) of FIG. 6, the adhesive layer 18 of the electronic device 1b may not fill up a space between the electronic unit 14 and the bottom surface BS and may include, for example, a portion P1 and a portion P2 separated from each other. The portion P1 and the portion P2 are adjacent to the left side and right side of the electronic unit 14, respectively. When a central part of the bottom surface BS of the recess RE is a protrusion, and part of the bottom surface BS adjacent to the sidewall is a groove, the portion P1 and the portion P2 may help fill the groove by disposing the portion P1 and the portion P2 adjacent to two sides of the electronic unit 14, so that the electronic unit 14 is leveled. The portion P1 overlaps the electronic unit 14 in the direction DR3, and they have an overlapping width W3. The portion P2 overlaps the electronic unit 14 in the direction DR3, and they have an overlapping width W4. A ratio of a sum of the overlapping width W3 and the overlapping width W4 to a width W5 of the electronic unit 14 in the direction DR1 may be greater than or equal to 0.3 and less than or equal to 1 (i.e., 0.3≤(overlap width W3+overlap width W4)/width W5≤1). In FIG. 6, the insulating layer IN1 may be disposed in a gap between the portion P1 and the portion P2, but the present disclosure is not limited thereto. In some embodiments, the electronic device 1b may further include an underfill disposed in the gap between the portion Pl and the portion P2.

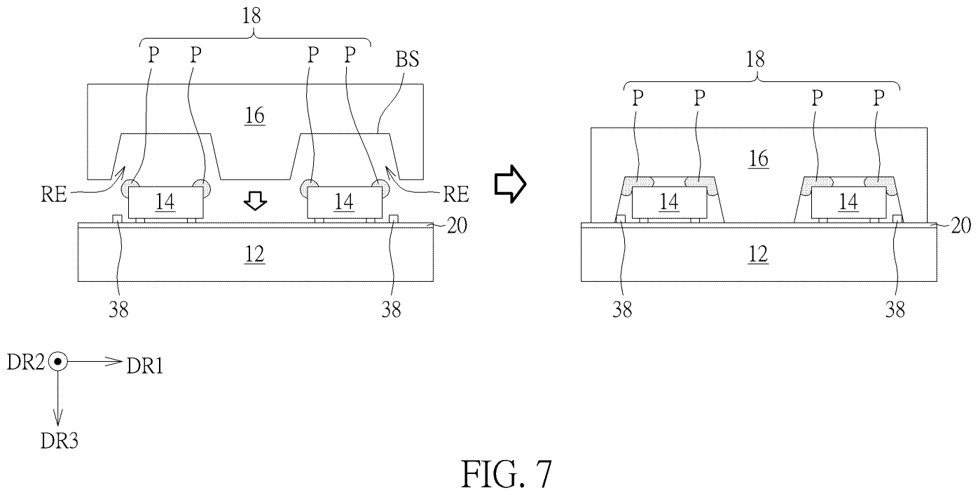

Refer to FIG. 7, which schematically illustrates cross-sectional views of structures in the step of providing the adhesive layer on the electronic units and the step of fixing the electronic units on the substrate according to some embodiments of the present disclosure. As shown in FIG. 7, the manufacturing method of the electronic device 1 may further include providing a plurality of spacers 38, wherein the spacers 38 are disposed on the carrier 12 and correspond to the recesses RE. For example, as shown in the left portion of FIG. 7, the step of providing the carrier 12 may include forming the spacers 38 on the release layer 20 (or the carrier 12) to reduce the risk of the relative position of the substrate 16 and the electronic unit 14 being offset in a horizontal direction (e.g., direction DR1), thereby improving the position consistency of the electronic units 14 fixed on the substrate 16. In this embodiment, the number of the spacers 38 may be at least two, wherein the two spacers 38 may correspond to different recesses RE, but not limited thereto. In some embodiments, different spacers 38 may alternatively correspond to the same recess RE.

As shown in the right portion of FIG. 7, in the step of fixing the electronic units 14 on the substrate 16, the substrate 16 may be moved downward until the sidewalls of the recesses RE respectively contact the spacers 38, such that the position of the substrate 16 in the horizontal direction (e.g., direction DR1) may be fixed by the engagement with the spacer 38. Accordingly, the position consistency of the electronic units 14 may be improved. The heights of the spacers 38 may be adjusted, for example, according to the positions and taper angles of the sidewalls of the corresponding recesses RE or other conditions. In this case, during the step of removing the carrier 12, the spacers 38 are also removed simultaneously, that is to say, the step of removing the carrier 12 may further include removing the spacers 38. In some embodiments, the spacers 38 shown in FIG. 7 may be used in the manufacturing method of the electronic device in any of the above or below embodiments.

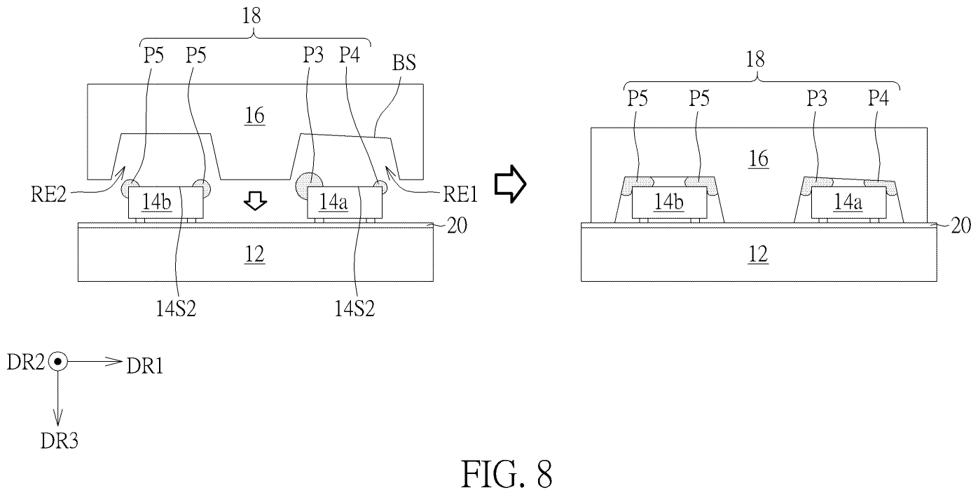

Refer to FIG. 8, which schematically illustrates cross-sectional views of structures in the step of providing the adhesive layer on the electronic units and the step of fixing the electronic units on the substrate according to some embodiments of the present disclosure. As shown in FIG. 8, the amount of a portion of the adhesive layer 18 provided on one of the electronic units 14 may be different from the amount of another portion of the adhesive layer 18 provided on another of the electronic units 14. Specifically, as shown in the left portion of FIG. 8, the adhesive layer 18 may include a portion P3, a portion P4, and two portions P5, wherein the portion P3 and the portion P4 may be respectively located at two corners of the electronic unit 14a, and the portions P5 are respectively located at two corners of the electronic unit 14b. In FIG. 8, the recess RE1 corresponding to the electronic unit 14a has an asymmetric structure, and for example, the bottom surface BS of the recess RE1 is not parallel to the horizontal direction (e.g., the direction DR1) and/or the sidewall of the recess RE1 is not symmetrical with respect to the direction DR3. FIG. 8 takes a depth of left side of the recess RE1 being greater than a depth of right side of the recess RE1 as an example, but not limited thereto. In this case, the amount of the portion P3 of the adhesive layer 18 corresponding to the left side of the recess RE1 may be greater than the amount of the portion P4 of the adhesive layer 18 corresponding to the right side of the recess RE1, so that while the electronic unit 14a is fixed in the recess RE1, the levelness of the surface 14S2 of the electronic unit 14a may not be affected by the asymmetric recess RE1 and may still be parallel to the direction DR1, as shown in the right portion of FIG. 8. In addition, when the recess RE2 corresponding to the electronic unit 14b has a symmetrical structure, the amount of one of the portions P5 of the adhesive layer 18 corresponding to the left side of the recess RE2 may be the same as the amount of another of the portions P5 corresponding to the right side of the recess RE2, so that the surface 14S2 of the electronic unit 14b may maintain a certain levelness. Therefore, the ratio of the amount of the portion P3 to the amount of the portion P4 is different from the ratio of the amount of one of the portions P5 to the amount of another of the portions P5. In this case, the total amount of the portion P3 and the portion P4 corresponding to the electronic unit 14a may be the same as or different from the total amount of the portions P5 corresponding to the electronic unit 14b. In some embodiments, the adhesive layer 18 shown in FIG. 8 may be used in the manufacturing method of the electronic device in any of the above or below embodiments.

Refer to FIG. 9, which schematically illustrates cross-sectional views of structures in the step of providing the adhesive layer on the electronic units and the step of fixing the electronic units on the substrate according to some embodiments of the present disclosure. As shown in the left portion of FIG. 9, the release layer 20 may have a plurality of first portions 20P1 and a plurality of second portions 20P2, wherein each first portion 20P1 is disposed between two adjacent second portions 20P2, and the first portions 20P1 and the second portions 20P2 may have different thicknesses. Furthermore, the electronic units 14 may be disposed on the corresponding first portions 20P1, respectively. In the embodiment of FIG. 9, a width of one of the first portions 20P1 in the direction DR1 may be less than a width of one of the recesses RE in the direction DR1, for example, less than a width of the bottom surface BS of the recess RE. The release layer 20 may include a single layer or multilayer structure.

As shown in the right portion of FIG. 9, in the step of fixing the electronic units 14 on the substrate 16, since the thickness of one of the first portions 20P1 disposed between the corresponding electronic unit 14 and the carrier 12 is greater than that of one of the second portions 20P2 between the first surface 16S1 of the substrate 16 and the carrier 12, the first portions 20P1 may provide a buffering effect when the substrate 16 is pressed down, so as to reduce or avoid the risk that the substrate 16 is broken while being pressed down. In some embodiments, the release layer 20 shown in FIG. 9 may be used in the manufacturing method of the electronic device in any of the above or below embodiments.

Refer to FIG. 10, which schematically illustrates a cross-sectional view of an electronic device according to a second embodiment of the present disclosure. The electronic device 2 of this embodiment differs from the electronic device 1 of FIG. 3 in that the electronic device 2 may further include another circuit structure 40 disposed on a side of the substrate 16 away from the circuit structure 28. The circuit structure 40 may be electrically connected to the circuit structure 28 through the through via structure TS. The structure of the circuit structure 40 may be similar to that of the circuit structure 28 and may include at least one conductive layer CL2 and at least one insulating layer IN2, so the above contents may be referred to for the circuit structure 40, and it will not be detailed redundantly.

In the embodiment of FIG. 10, an insulating layer IN3 may be formed in each recess RE between the step of forming the through via structure TS and the step of forming the circuit structure 28 (or forming the insulating layer IN1), such that the insulating layer IN3 may at least surround the electronic units 14. In addition, the insulating layer IN3 may have a plurality of openings OP to expose the pads 14p of the electronic unit 14, respectively. The insulating layer IN3 may include, for example, polyimide (PI), photosensitive polyimide (PSPI), Ajinomoto build-up film (ABF), silicon oxide (SiOx), silicon nitride (SiNx), silicon oxynitride (SiOxNy) or other suitable dielectric materials. The material of the insulating layer IN3 may be the same as or different from that of the insulating layer IN1.

As shown in FIG. 10, the electronic device 2 may further include a protective layer 42 disposed on the circuit structure 28 and the first surface 16S1 of the substrate 16 to protect the circuit structure 28. The protective layer 42 may have a plurality of openings to expose the pads 28p of the circuit structure 28, respectively, so that the pads 30p of the electronic unit 30a and the pads 30p of the electronic unit 30b may be bonded to the pads 28p of the circuit structure 28 through the corresponding bonding pads 44. In some embodiments, the electronic device 2 may further include another protective layer 46 disposed on the circuit structure 40 and the second surface 16S2 of the substrate 16 to protect the circuit structure 40. The protective layer 46 may have a plurality of openings to expose the pads 40p of the circuit structure 40, so that the bonding pads 48 may be respectively bonded to the corresponding pads 40p of the circuit structure 40. The protective layer 42 and the protective layer 46 may each include a solder resist material or other suitable materials. The bonding pads 44 and the bonding pads 48 may include, for example, solder balls, nickel, gold, copper, gallium or other suitable conductive materials.

In one embodiment, the electronic unit 30a may be, for example, a control chip, and the electronic unit 30b may be, for example, a photonic integrated circuit. The electronic unit 30b may, for example, include an assembly structure of a photoelectric conversion element, an optical waveguide, signal a processing element, a micro-electromechanical element, and/or other suitable elements. In this case, the electronic device 2 may further optionally include an optical fiber 50 assembled on the electronic unit 30b, such that the electronic unit 30b may receive an optical signal through the optical fiber 50.

In FIG. 10, the electronic device 2 may further optionally include an adhesive layer 52 disposed between the electronic unit 30a and the circuit structure 28 and between the electronic unit 30b and the circuit structure 28. The electronic device 2 may further optionally include a protective layer 54 disposed on the circuit structure 28, and the protective layer 54 at least surrounds the electronic unit 30a and the electronic unit 30b. In this embodiment, the protective layer 54 extends to a side of the circuit structure 28 and may surround the electronic unit 30a, the electronic unit 30b, and the circuit structure 28, but not limited thereto. In some embodiments, the protective layer 54 may further extend to a side of the substrate 16 and surround the substrate 16. The protective layer 54 may include an encapsulation material, such as epoxy molding compound (EMC) or other suitable materials. Other parts of the electronic device 2 and other steps of its manufacturing method of this embodiment may be identical or similar to the embodiment of FIG. 3, so the above contents may be referred to for them, and they are not detailed redundantly. In some embodiments, the electronic device 2 and the manufacturing method thereof of this embodiment may also adopt the electronic device la or the electronic device 1b of FIG. 6 or one of the manufacturing methods of FIGS. 7 to 9.

Refer to FIG. 11, which schematically illustrates a cross-sectional view of an electronic device according to a third embodiment of the present disclosure. As shown in FIG. 11, the electronic device 3 of this embodiment differs from the electronic device 2 shown in FIG. 10 in that the electronic device 3 further includes a buffer layer 22. In the embodiment of FIG. 11, the buffer layer 22 may extend from the first surface 16S1 to the second surface 162 through the sidewall of the through hole TH1 and may be a continuous layer. In some embodiments, the buffer layer 22 may be disposed on at least a portion of the sidewall of the through hole TH1. In some embodiments, the buffer layer 22 may not extend to the bottom surface BS of the recess RE, but not limited thereto. In some embodiments, the buffer layer 22 may be disposed on at least a portion of the sidewall of the recess RE, but not limited thereto.

In the embodiment of FIG. 11, when the buffer layer 22 is provided in the recess RE, the adhesive layer 18 may optionally contact the buffer layer 22, but not limited thereto. In some embodiments, when the buffer layer 22 extending into the recess RE is small, the buffer layer 22 may not contact the adhesive layer 18. Other parts of the electronic device 3 and other steps of its manufacturing method of this embodiment may be identical or similar to the embodiment of FIG. 3 or the embodiment of FIG. 10, so the above contents may be referred to for them, and they are not detailed redundantly. In some embodiments, the electronic device 3 and its manufacturing method of this embodiment may also adopt the electronic device la or the electronic device 1b of FIG. 6 or one of the manufacturing methods of FIG. 7 to FIG. 9.

In summary, in the manufacturing method of the electronic device of the present disclosure, the back surfaces of the electronic units are fixed in the recesses of the substrate by the adhesive layer, and the levelness and position consistency of the electronic units fixed in the recesses may be improved in the case that flatness of the bottom surfaces of the recesses is not good. As a result, the impact on the resolution of the circuit structure formed subsequently may be lowered, or the yield of the subsequent process may be improved. In addition, the manufacturing method of the present disclosure may further include inspecting the recesses, and providing the amounts of different portions of the adhesive layer on different electronic units according to the states of the recesses to improve the position consistency of different electronic units relative to the first surface of the substrate. According to some embodiments of the present disclosure, the manufacturing method of the present disclosure may further include forming the spacers on the release layer to reduce the risk of the relative position of the substrate and the electronic units being offset in the horizontal direction. According to some embodiments of the present disclosure, the manufacturing method of the present disclosure may further include forming the release layer having portions with different thicknesses to reduce or avoid the risk that the substrate is cracked while being pressed down. According to the electronic device of the present disclosure, the electronic units may further be fixed in the recesses using the adhesive layer with better support and the adhesive layer with better leveling. In the electronic device of the present disclosure, the through via structure may not protrude from the first surface and the second surface of the substrate or the outer surface of the buffer layer located on the first surface and the second surface to reduce or avoid cracks at the corners of the substrate.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A manufacturing method of an electronic device comprising:
providing a carrier;
providing a plurality of electronic units on the carrier;
providing a substrate having a plurality of recesses;
providing an adhesive layer on the plurality of electronic units or in the plurality of recesses, such that the plurality of electronic units are fixed on the substrate through the adhesive layer, and the plurality of electronic units are located in the plurality of recesses, respectively;
removing the carrier;
providing an insulating layer disposed on the plurality of electronic units and extended into the plurality of recesses; and
providing a conductive structure disposed on the insulating layer, wherein the conductive structure penetrates through the insulating layer to be electrically connected to at least one of the plurality of electronic units.

2. The manufacturing method of the electronic device according to claim 1, further comprising inspecting the plurality of recesses and providing an amount of the adhesive layer according to states of the plurality of recesses.

3. The manufacturing method of the electronic device according to claim 1, wherein an amount of the adhesive layer provided on one of the plurality of electronic units is different from an amount of the adhesive layer provided on another of the plurality of electronic units.

4. The manufacturing method of the electronic device according to claim 1, wherein providing the adhesive layer on the plurality of electronic units comprises coating the adhesive layer on a portion of a back surface of one of the plurality of electronic units and exposing another portion of the back surface.

5. The manufacturing method of the electronic device according to claim 4, wherein the portion of the back surface is four corners of the back surface.

6. The manufacturing method of the electronic device according to claim 4, wherein the adhesive layer comprises two portions respectively located at two corners of the back surface, and an amount of one of the two portions is different from an amount of another of the two portions.

7. The manufacturing method of the electronic device according to claim 1, further comprising providing a plurality of spacers, wherein the plurality of spacers are disposed on the carrier and correspond to the plurality of recesses.

8. The manufacturing method of the electronic device according to claim 7, wherein removing the carrier comprises removing the plurality of spacers.

9. The manufacturing method of the electronic device according to claim 1, wherein providing the substrate comprises forming at least one through hole in the substrate, and the manufacturing method further comprises forming a through via structure in the at least one through hole after removing the carrier.

10. The manufacturing method of the electronic device according to claim 1, wherein providing the carrier comprising disposing a release layer on the carrier, wherein the release layer comprises a plurality of first portions and a plurality of second portions, each of the plurality of first portions is disposed between two of the plurality of second portions, and the first portions and the second portions have different thicknesses.

11. An electronic device comprising:
a substrate having at least one recess;
at least one electronic unit disposed in the at least one recess;
a first adhesive layer disposed between the at least one electronic unit and a bottom surface of the at least one recess;
an insulating layer disposed on the at least one electronic unit and extended into the at least one recess; and
a conductive structure disposed on the insulating layer, and the conductive structure penetrating through the insulating layer to be electrically connected to the at least one electronic unit;
wherein a surface roughness of the at least one recess is greater than a surface roughness of the at least one electronic unit.

12. The electronic device according to claim 11, further comprising a second adhesive layer disposed between the at least one electronic unit and the first adhesive layer.

13. The electronic device according to claim 12, wherein a leveling property of the second adhesive layer is greater than a leveling property of the first adhesive layer.

14. The electronic device according to claim 11, wherein at least a portion of the insulating layer is located between a sidewall of the at least one electronic unit and a sidewall of the at least one recess.

15. The electronic device according to claim 11, wherein a ratio of an overlapping area of the adhesive layer and the back surface of the at least one electronic unit to an area of the back surface of the at least one electronic unit is greater than or equal to 0.1 and less than or equal to 1.

16. The electronic device according to claim 11, wherein a distance between a horizontal plane of a surface of the at least one electronic unit away from the bottom surface of the at least one recess and a horizontal plane of a first surface of the substrate adjacent to the surface of the at least one electronic unit is less than or equal to 10 micrometers.

17. The electronic device according to claim 11, wherein the substrate further has at least one through hole, and the electronic device further comprises at least one through via structure in the at least one through hole.

18. The electronic device according to claim 17, wherein a projection of the through via structure along a top view direction of the electronic device on a horizontal plane perpendicular to the top view direction does not overlap projections of a first surface and a second surface of the substrate opposite to each other along the top view direction on the horizontal plane.

19. The electronic device according to claim 11, wherein a ratio of a height from a highest point of the adhesive layer to a horizontal plane of a surface of the at least one electronic unit to a thickness of the at least one electronic unit is greater than or equal to 0.2 and less than or equal to 0.8.

20. The electronic device according to claim 11, further comprising at least another electronic unit disposed on the conductive structure, wherein the at least another electronic unit is electrically connected to the at least one electronic unit through the conductive structure.
